(19) United States
(12) Patent Application Publication
(10) Pub. No.: US 2013/0057794 A1
(43) Pub. Date: Mar. 7, 2013

(54) PIXEL STRUCTURE FOR LIQUID CRYSTAL DISPLAY PANEL AND LIQUID CRYSTAL DISPLAY PANEL COMPRISING THE SAME

(71) Applicants: Hung-lung Hou, Shenzhen (CN); Chengming He, Shenzhen (CN)

(72) Inventors: Hung-lung Hou, Shenzhen (CN); Chengming He, Shenzhen (CN)

(73) Assignee: Shenzhen China Star Optoelectronics Technology Co. Ltd., Shenzhen, Guangdong (CN)

(21) Appl. No.: 13/320,026

(22) PCT Filed: Sep. 20, 2011
(86) PCT No.: PCT/CN11/79849

§ 371 Date: Nov. 11, 2011

(30) Foreign Application Priority Data
Sep. 6, 2011 (CN) 201110262675.X

(51) Int. Cl. G02F 1/136; H01L 33/16

(52) U.S. Cl. 349/43; 257/59; 257/72; 257/E33.053

(57) ABSTRACT

A pixel structure for an LCD panel comprises at least one gate line, a storage line, a lower-substrate pixel electrode and a first switch unit. The at least one gate line is configured to input a scanning signal to the first switch unit; the first switch unit is connected to the at least one gate line, the storage line and the lower-substrate pixel electrode respectively, and is configured to receive the scanning signal and transfer an electric signal from the storage line to the lower-substrate pixel electrode according to the scanning signal. The pixel structure and the LCD panel comprising the pixel structure can reduce the number of pads to simplify design of the peripheral circuit; and because the data line is not used for signal transferring; even disconnection of the data line will not affect the curing effect of the UV process.

### BACKGROUND

1. Technical Field

The present invention relates to the field of liquid crystal displaying, and more particularly, to a pixel structure for a liquid crystal display (LCD) panel and a liquid crystal display panel comprising the pixel structure.

2. Description of Related Art

As a core part of an LCD, an LCD panel mainly consists of an array substrate and a color film substrate laminated together and liquid crystals sandwiched therebetween. The array substrate comprises a plurality of displaying units formed by scan lines and data lines intersected with each other. Each display unit corresponds to a pixel structure, and through the pixel structure, twisting of liquid crystal molecules in a region corresponding to the display unit can be controlled so as to display an image.

PSVA (polymer stabilization vertical alignment) is a technology that utilizes a kind of new material to improve the displaying effect of an LCD. According to the PSVA technology, a hardening monomer is incorporated into the liquid crystal material, and after the substrates are laminated together, the monomer is activated by applying a voltage and irradiating ultraviolet (UV) light. Thus, the monomer can react with the polymer layer to result in a fixed pre-tilt angle of the liquid crystal molecules.

LCD panels adopting the PSVA technology have a high contrast ratio and high light transmissivity. However, a curing process is additionally needed in the manufacturing process. Prior to the curing process, a given voltage must be applied to drive the liquid crystal molecules into the operation status and then the UV curing process is carried out. Therefore, provision must be made for supplying signals from the peripheral circuit to pixels in the operational region (AA region) so as to keep the liquid crystal molecules in the operation status. A common practice is to dispose corresponding pads along a periphery of the panel, and through wiring along the periphery, signals are inputted to the pixels via data lines and gate lines to drive the liquid crystal molecules into the operation status necessary for the curing process.

The greater the number of pads is, the more difficult it is to design the wiring. For example, as shown in FIG. 1 and FIG. 2, the pixel structure of the LCD panel comprises two gate lines 200, two thin film transistors (TFTs) 401 and 402, one data line 100, one storage line 500, a lower-substrate pixel electrode 302 and an upper-substrate pixel electrode 301. Accordingly, seven pads need to be disposed along the periphery of the LCD panel; specifically, the data line 100 corresponds to three pads of the red color, the green color and the blue color (RGB) respectively, each of the two gate lines 200 corresponds to one pad, the storage line 500 corresponds to one pad, and the upper-substrate pixel electrode 301 of the color film substrate corresponds to one pad. The data line 100 is configured to input a signal, and when the TFT 401 is turned on, the signal from the data line 100 is transferred to the lower-substrate (array substrate) pixel electrode 302 via the TFT 401. Then, an alternate current (AC) signal is applied to the upper-substrate (color film substrate) pixel electrode 301 so that a voltage difference is applied to the liquid crystal molecules between the two substrates, and then a UV process is carried out to fix the pre-tilt angle of the liquid crystal molecules.

If inconsistency of voltage differences exists in a certain pixel region, for example, if the data line 100 in this pixel region is disconnected, it will be impossible for the signal to be transferred to the lower-substrate pixel electrode 302. In this case, because no voltage is applied to the lower-substrate pixel electrode 302, liquid crystal molecules in the corresponding region are in a “floating” status. Then, when the AC signal on the upper-substrate pixel electrode 301 changes, the lower-substrate pixel electrode 302 will also experience a slight change in voltage level, which leads to a smaller voltage difference between the two substrates and variation of the fixed pre-tilt angle. Consequently, optical performance varies across the LCD panel to cause the so-called mura phenomenon in images displayed.

According to the above descriptions, as this technology requires use of many pads along the periphery of the LCD panel, design of the circuit is rather complicated; besides, in case of disconnection of the data line 100, the mura phenomenon will also be caused after the UV curing process. Accordingly, a need exists in the art to provide a pixel structure and an LCD panel comprising the pixel structure that require use of fewer pads and have a simple circuit design and that can prevent influence of disconnection of the data line 100 on the UV curing process.

### SUMMARY

A primary objective of the present invention is to provide a pixel structure and an LCD panel comprising the pixel structure that require use of fewer pads and have a simple circuit design.

To achieve this objective, the present invention provides a pixel structure for a liquid crystal display (LCD) panel, comprising: a first gate line, a second gate line, a data line, a storage line, a lower-substrate pixel electrode, a first switch unit and a second switch unit. A region enclosed by the first gate line, the second gate line, the data line and an adjacent data line forms a pixel region, and the lower-substrate pixel electrode is located in the pixel region; the first switch unit and the second switch unit are both a thin film transistor (TFT); the first switch unit has a gate connected to the first gate line, a source connected to the storage line and a drain connected to the lower-substrate pixel electrode, and the first switch unit is configured to receive a scanning signal from the first gate line and transfer an electric signal from the storage line to the lower-substrate pixel electrode according to the scanning signal; the second switch unit has a gate connected to the second gate line, a source connected to the data line and a drain connected to the lower-substrate pixel electrode, and the second switch unit is configured to receive a scanning signal from the second gate line and transfer an electric signal from the data line to the lower-substrate pixel electrode according to the scanning signal.

Preferably, the pixel structure further comprises a storage capacitor connected between the storage line and the lower-substrate pixel electrode, an upper-substrate pixel electrode is disposed at a side opposite to the lower-substrate pixel electrode, and liquid crystal molecules are sandwiched between the lower-substrate pixel electrode and the upper-substrate pixel electrode.

Preferably, the data line is connected to an external data driver, and both the first gate line and the second gate line are connected to an external scanning driver.

Preferably, each of the first gate line, the storage line and the upper-substrate pixel electrode is connected with one pad.

The present invention further provides a pixel structure for an LCD panel, which comprises at least one gate line, a storage line, a lower-substrate pixel electrode and a first switch unit;

the at least one gate line is configured to input a scanning signal to the first switch unit;

the first switch unit is connected to the at least one gate line, the storage line and the lower-substrate pixel electrode respectively, and is configured to receive the scanning signal from the at least one gate line and transfer an electric signal from the storage line to the lower-substrate pixel electrode according to the scanning signal.

Preferably, the pixel structure further comprises a data line and a second switch unit, the lower-substrate pixel electrode is located in a pixel region defined by the data line and the gate line, the second switch unit is connected to the at least one gate line, the data line and the lower-substrate pixel electrode respectively, and the second switch unit is configured to receive a scanning signal from the at least one gate line and transfer an electric signal from the data line to the lower-substrate pixel electrode according to the scanning signal.

Preferably, the at least one gate line comprises a charging gate line and a shunting gate line, and the first switch unit comprises a first charging TFT and a first shunting TFT; and

the first charging TFT has a gate connected to the charging gate line, a source connected to the storage line and a drain connected to the first shunting TFT, and the first shunting TFT has a gate connected to the shunting gate line, a source connected to the first charging TFT and a drain connected to the lower-substrate pixel electrode respectively.

Preferably, the data line is connected to an external data driver, and both the charging gate line and the shunting gate line are connected to an external scanning driver.

Preferably, each of the charging gate line, the shunting gate line, the storage line and the upper substrate pixel electrode is connected with one pad.

Preferably, the second switch unit comprises a second charging TFT and a second shunting TFT, the second charging TFT has a gate connected to the charging gate line, a source connected to the data line and a drain connected to the lower-substrate pixel electrode, and the second shunting TFT has a gate connected to the shunting gate line, a source connected to the storage line and a drain connected to the lower-substrate pixel electrode.

Preferably, the pixel structure further comprises a storage capacitor connected between the storage line and the lower-substrate pixel electrode, an upper-substrate pixel electrode is disposed at a side opposite to the lower-substrate pixel electrode, and liquid crystal molecules are sandwiched between the lower-substrate pixel electrode and the upper-substrate pixel electrode.

The present invention further provides an LCD panel, comprising an array substrate having a plurality of pixel structures arrayed thereon, wherein each of the pixel structures comprises at least one gate line, a storage line, a data line, a lower-substrate pixel electrode, a first switch unit and a second switch unit;

the at least one gate line is configured to input a scanning signal to the first switch unit;

the first switch unit is connected to the at least one gate line, the storage line and the lower-substrate pixel electrode respectively, and is configured to receive the scanning signal from the at least one gate line and transfer an electric signal from the storage line to the lower-substrate pixel electrode according to the scanning signal; and

the lower-substrate pixel electrode is located in a pixel region defined by the data line and the gate line, the second switch unit is connected to the at least one gate line, the data line and the lower-substrate pixel electrode respectively, and the second switch unit is configured to receive a scanning signal from the at least one gate line and transfer an electric signal from the data line to the lower-substrate pixel electrode according to the scanning signal.

Preferably, the at least one gate line comprises a charging gate line and a shunting gate line, and the first switch unit comprises a first charging TFT and a first shunting TFT;

the first charging TFT has a gate connected to the charging gate line, a source connected to the storage line and a drain connected to the first shunting TFT, and the first shunting TFT has a gate connected to the shunting gate line, a source connected to the first charging TFT and a drain connected to the lower-substrate pixel electrode respectively.

Preferably, the second switch unit comprises a second charging TFT and a second shunting TFT, the second charging TFT has a gate connected to the charging gate line, a source connected to the data line and a drain connected to the lower-substrate pixel electrode, and the second shunting TFT has a gate connected to the shunting gate line, a source connected to the storage line and a drain connected to the lower-substrate pixel electrode.

Preferably, each of the charging gate line, the shunting gate line, the storage line and the upper substrate pixel electrode is connected with one pad.

Preferably, the at least one gate line includes a first gate line and a second gate line, and the first switch unit and the second switch unit both are a TFT;

the first switch unit has a gate connected to the first gate line, a source connected to the storage line and a drain connected to a lower-substrate pixel electrode, and the first switch unit is configured to receive a scanning signal from the first gate line and transfer an electric signal from the storage line to the lower-substrate pixel electrode according to the scanning signal; and

the second switch unit has a gate connected to the second gate line, a source connected to the data line and a drain connected to the lower-substrate pixel electrode, and the second switch unit is configured to receive a scanning signal from the second gate line and transfer an electric signal from the data line to the lower-substrate pixel electrode according to the scanning signal.

Preferably, the first gate line is shared by adjacent rows of pixel structures on the array substrate, the first gate line is located at a boundary between the adjacent rows of pixel structures, the data line of each of the pixel structures on the array substrate is connected to an external data driver, and the gate line of each of the pixel structures is connected to an external scanning driver.

Preferably, each of the first gate line, the storage line and the upper-substrate pixel electrode is connected with one pad.

The pixel structure for an LCD panel and the LCD panel comprising the pixel structure of the present invention require use of fewer pads and have a simple circuit design, and can prevent occurrence of the mora phenomenon due to influence of disconnection of the data line on the UV curing process.

### BRIEF DESCRIPTION OF THE DRAWINGS

FIG. 1 is a schematic view of a pixel structure for an LCD panel in the prior art;

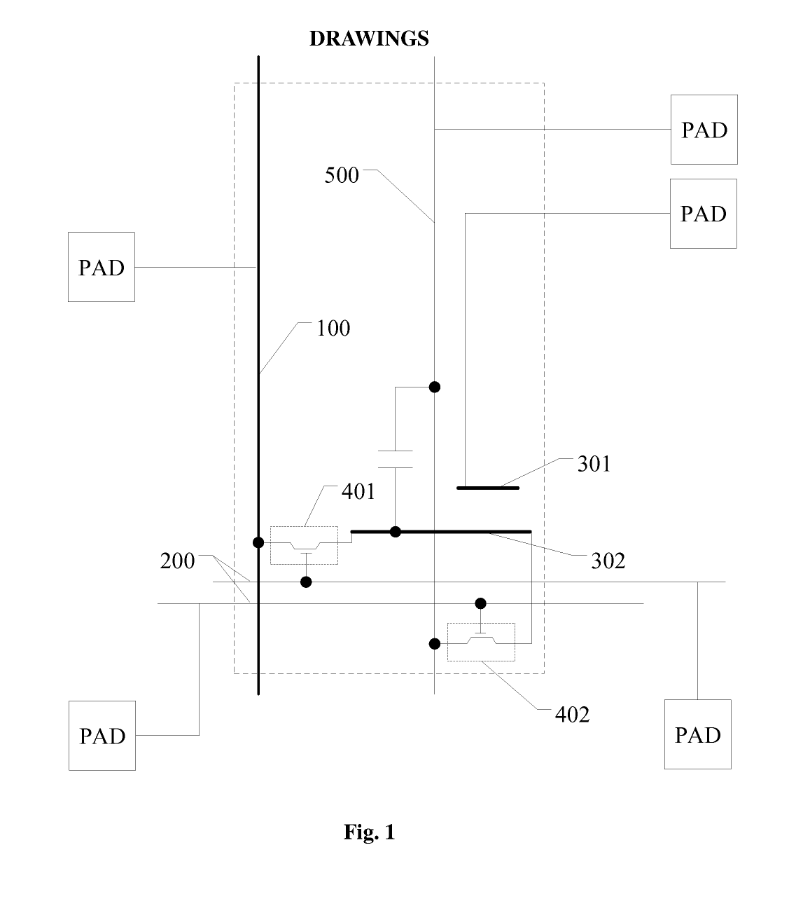

FIG. 2 is a schematic structural view of an LCD panel in the prior art;

FIG. 3 is a schematic structural view of a first embodiment of a pixel structure for an LCD panel according to the present invention;

FIG. 4 is a schematic view of an equivalent circuit of the pixel structure for an LCD panel shown in FIG. 3;

FIG. 5 is a schematic structural view of an LCD panel comprising the pixel structure shown in FIG. 3;

FIG. 6 is a schematic structural view of a second embodiment of the pixel structure for an LCD panel according to the present invention;

FIG. 7 is a schematic view of an equivalent circuit of a pixel structure for an LCD panel shown in FIG. 6; and

FIG. 8 is a schematic structural view of an LCD panel comprising the pixel structure shown in FIG. 6.

Hereinafter, the present invention will be further described with reference to the attached drawings in order to make the technical solutions thereof more apparent.

### DETAILED DESCRIPTION

It shall be appreciated that, the embodiments described herein are only intended to illustrate but not to limit the present invention.

According to the technical solutions of the present invention, a TFT path is provided between a storage line and a lower-substrate pixel electrode, and by controlling the gate line, the TFT path can be turned on to transfer a signal from the storage line to the lower-substrate pixel electrode. In this way, the number of pads is reduced, so the peripheral circuit is made simpler; and because the data line is not used for signal transferring, even disconnection of the data line will not affect the UV curing process.

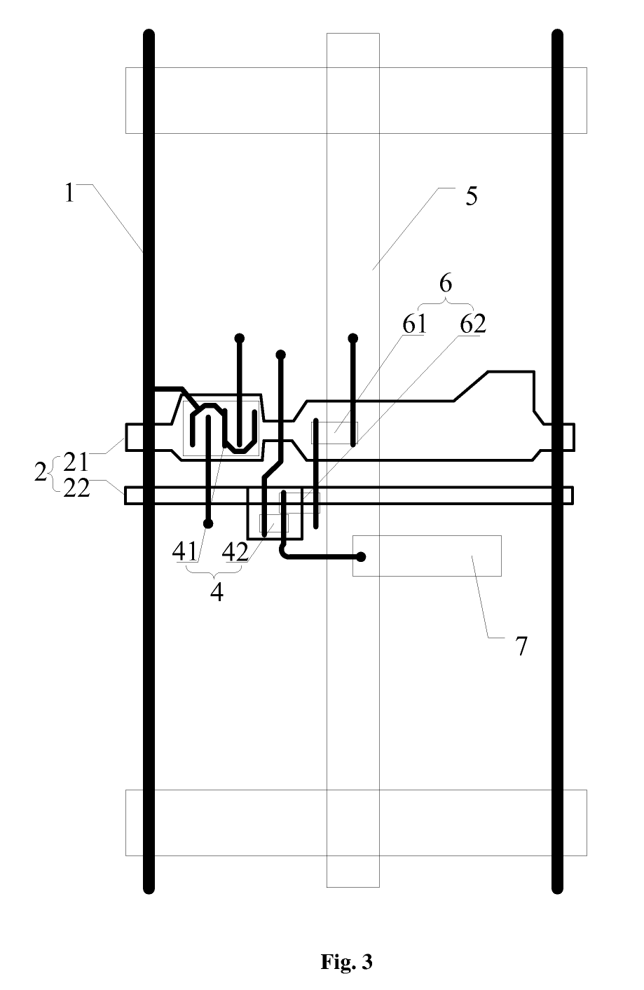

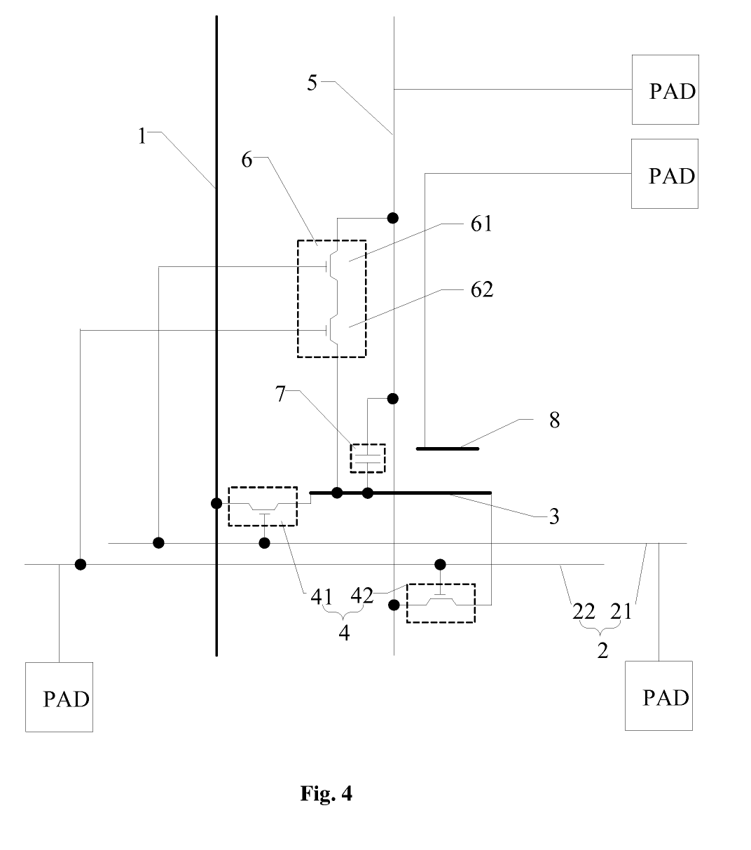

As shown in FIG. 3 and FIG. 4, a pixel structure for an LCD panel is provided in a first embodiment of the present invention. FIG. 3 is a schematic structural view of the pixel structure for an LCD panel in this embodiment, and FIG. 4 is a schematic view of an equivalent circuit of the pixel structure. The pixel structure for an LCD panel comprises a data line 1, gate lines 2, a lower-substrate pixel electrode 3, a first switch unit 6, a second switch unit 4, a storage line 5, a storage capacitor 7 and an upper-substrate pixel electrode 8. The first switch unit 6 comprises a first charging TFT 61 and a first shunting TFT 62, and the second switch unit 4 comprises a second charging TFT 41 and a second shunting TFT 42.

The gate lines 2 are configured to provide scanning signals for the TFTs of the switch units, and include a charging gate line 21 and a shunting gate line 22.

The data line 1 is perpendicular to the gate lines 2, and two adjacent data lines 1 intersect with two adjacent gate lines 2 to form a pixel region. The charging gate line 21 and the shunting gate line 22 are located in a middle portion of the pixel region to divide the pixel region into an upper pixel region and a lower pixel region.

The lower-substrate pixel electrode 3 is located in the pixel region defined by the data lines 1 and the gate lines 2. The lower-substrate pixel electrode 3 is not labeled in FIG. 3, but covers surfaces of the upper pixel region and the lower pixel region in FIG. 3. The lower-substrate pixel electrode 3 is electrically connected to the second charging TFT 41 and the second shunting TFT 42 to receive signals from the second charging TFT 41 and the second shunting TFT 42. An equivalent circuit is shown in FIG. 4.

The lower-substrate pixel electrode 3 is a pixel electrode on an array (TFT) substrate, the upper-substrate pixel electrode 8 is a pixel electrode on a color film (CF) substrate, and liquid crystals are sandwiched between the lower-substrate pixel electrode 3 and the upper-substrate pixel electrode 8.

The second switch unit 4 is configured to transfer a signal from the data line 1 to the lower-substrate pixel electrode 3 according to the scanning signal.

The second switch unit 4 is formed by the second charging TFT 41 and the second shunting TFT 42. The second charging TFT 41 has a gate connected to the charging gate line 21, a source connected to the data line 1 and a drain connected to the lower-substrate pixel electrode 3. The second shunting TFT 42 has a gate connected to the shunting gate 22, a source connected to the storage line 5 and a drain connected to the lower-substrate pixel electrode 3.

The storage line 5 is disposed in a bottom layer of the pixel structure, and together with the lower-substrate pixel electrode 3, forms a storage capacitor 7.

The first switch unit 6 is configured to transfer the signal from the storage line 5 to the lower-substrate pixel electrode 3 according to the scanning signal.

The first switch unit 6 comprises a first charging TFT 61 and a first shunting TFT 62. The first charging TFT 61 has a gate connected to the charging gate line 21, a source connected to the storage line 5 and a drain connected to the first shunting TFT 62. The first shunting TFT 62 has a gate connected to the shunting gate line 22, a source connected to the first charging TFT 61 and a drain connected to the lower-substrate pixel electrode 3.

When the charging gate line 21 and the shunting gate line 22 are turned on simultaneously, the signal on the storage line 5 is transferred to the lower-substrate pixel electrode 3 via the first charging TFT 61 and the first shunting TFT 62.

Specifically, when a COM signal is applied to the charging gate line 21 and the shunting gate line 22 simultaneously, the charging gate line 21 and the shunting gate line 22 are enabled simultaneously and the first charging TFT 61 and the first shunting TFT 62 are turned on simultaneously so that the COM signal is transferred to the upper pixel region and the lower pixel region via the first charging TFT 61 and the first shunting TFT 62 respectively. Thus, the pixel signal becomes the COM signal.

Then, an AC 20V signal is applied to the upper-substrate pixel electrode 8 so that the liquid crystal molecules between the upper substrate and the lower substrate experience a voltage difference of 20V. Next, a UV process is carried out to fix the pre-tilt angle of liquid crystal molecules in this operation status.

Although, when the charging gate line 21 and the shunting gate line 22 are enabled simultaneously, the first charging TFT 41 and the first shunting TFT 42 are also turned on, this will not inhibit the lower-substrate pixel electrode 3 from obtaining the COM signal because the signal is not inputted from the data line 1. Moreover, because the data line 1 is not used to input the signal, even disconnection of the data line 1 will not affect the curing effect of the UV process.

Because only when the charging gate line 21 and the shunting gate line 22 are enabled simultaneously can the signal on the storage line 5 be transferred via the TFT path to the lower-substrate pixel electrode 3, normal displaying of images on the LCD panel during use or testing of the panel will not be affected provided that the drive circuit enables the charging gate line 21 and the shunting line 22 separately.

In the prior art, signals are inputted into the pixel via the data line 1, so the data line 1 requires use of three pads (RGB pads). However, in this embodiment of the present invention, signals are inputted from the storage line 5 to the lower-substrate pixel electrode 3 not via the data line 1 but via the TFT path disposed between the storage line 5 and the lower-substrate pixel electrode 3, so the number of pads is reduced by three as compared to the prior art and design of the peripheral circuit becomes simpler.

Here, the second charging TFT 41, the second shunting TFT 42, the first charging TFT 61 and the first shunting TFT 62 may also be replaced by other switching elements.

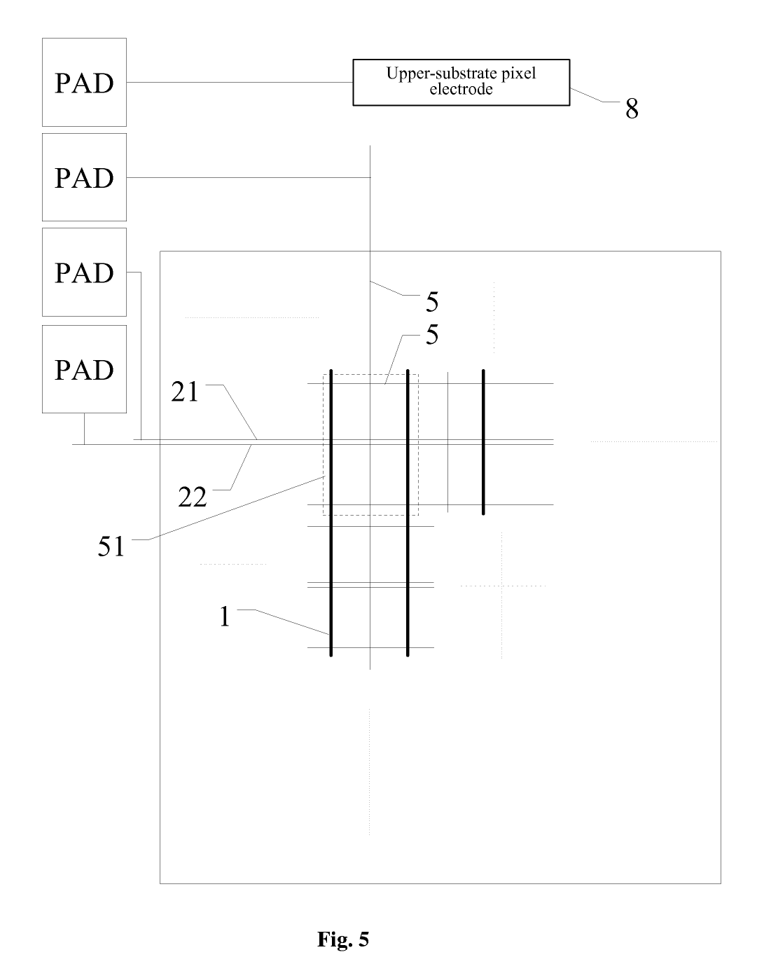

FIG. 5 shows an LCD panel according to the first embodiment of the present invention. A plurality of pixel structures 51 described in the first embodiment are arrayed on an array substrate of the LCD panel, with the data line 1 of each pixel structure 51 being connected to an external data driver. For the pixel structures 51 on the array substrate, the charging gate lines 21 thereof are connected in parallel and the shunting gate lines 22 are also connected in parallel, and both of them are connected to an external scanning driver. Along a periphery of the array substrate is disposed four pads corresponding to the charging gate lines 21, the shunting gate lines 22, the storage lines 5 and the upper-substrate pixel electrodes 8 respectively. The charging gate lines 21 are connected in parallel and then connected together to the corresponding pad; the shunting gate lines 22 are connected in parallel and then connected together to the corresponding pad; the storage lines 5 are connected in parallel and then connected to the corresponding pad; and the upper-substrate pixel electrodes 8 are connected in parallel and then connected together to the corresponding pad.

In this embodiment, the structures and working principles of the pixel structures 51 are just the same as those of the embodiment described with reference to FIG. 3 and FIG. 4, and will not be described again herein. In this embodiment, because only when the charging gate line 21 and the shunting gate line 22 are enabled simultaneously can signals on the storage line 5 be transferred via the TFT path to the lower-substrate pixel electrode 3, normal displaying of images on the LCD panel during use or testing of the panel will not be affected provided that the drive circuit enables the charging gate line 21 and the shunting line 22 separately.

In the prior art, signals are inputted into the pixel via the data line 1, so the data line 1 requires use of three pads (RGB pads). However, in this embodiment of the present invention, signals are inputted from the storage line 5 to the lower-substrate pixel electrode 3 not via the data line 1 but via the TFT path disposed between the storage line 5 and the lower-substrate pixel electrode 3, so only four pads are needed (i.e., the number of pads is reduced by three as compared to the prior art) and design of the peripheral circuit becomes simpler.

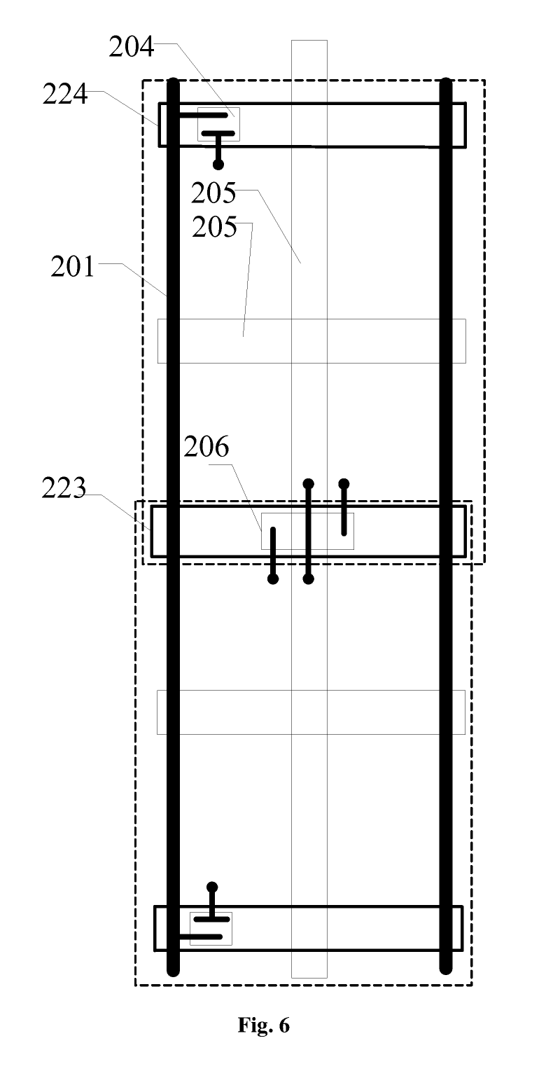

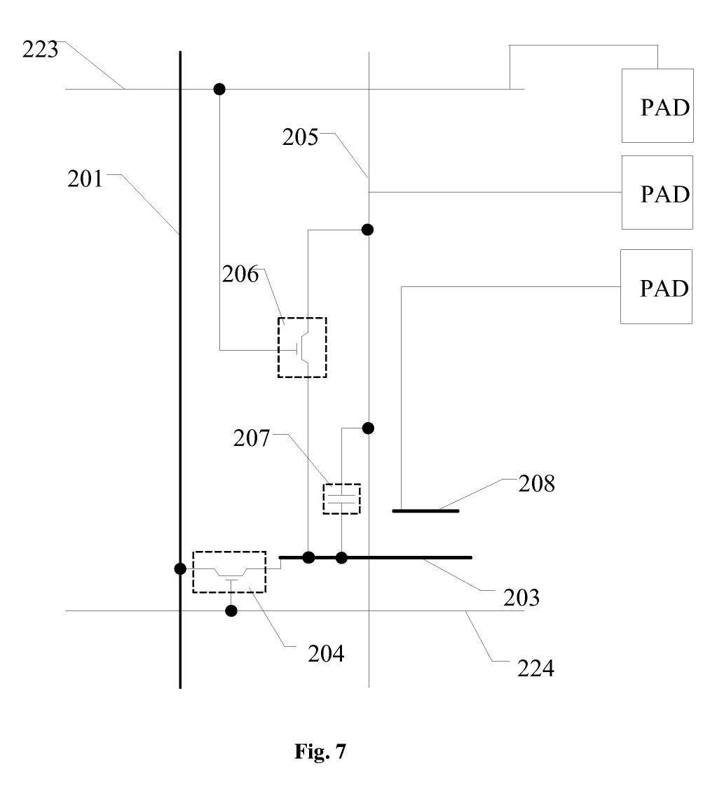

FIG. 6 and FIG. 7 show a pixel structure for an LCD panel according to a second embodiment of the present invention. FIG. 6 is a schematic structural view of the pixel structure for an LCD panel according to this embodiment, and FIG. 7 is a schematic view of an equivalent circuit of the pixel structure. The pixel structure for an LCD panel comprises gate lines, a data line 201, a lower-substrate pixel electrode 203, a first switch unit 206, a second switch unit 204, a storage line 205 and an upper-substrate pixel electrode 208.

The gate lines are configured to provide scanning signals for the TFTs of the switch units, and include a first gate line 223 and a second gate line 224.

The data line 201 intersects with the second gate line 224, and a region enclosed by the first gate line 223, the second gate line 224 and two adjacent data lines 201 forms a pixel region.

The lower-substrate pixel electrode 203 is located in the pixel region. The lower-substrate pixel electrode 203 is not labeled in FIG. 6, but covers the surface of the pixel region in FIG. 6. The lower-substrate pixel electrode 3 is electrically connected to the second switch unit 204 to receive signals transferred from the second switch unit 204. An equivalent circuit is shown in FIG. 7.

The lower-substrate pixel electrode 203 is a pixel electrode on an array (TFT) substrate, the upper-substrate pixel electrode 208 is a pixel electrode on a color film (CF) substrate, and liquid crystals are sandwiched between the lower-substrate pixel electrode 203 and the upper-substrate pixel electrode 208.

The second switch unit 204 is configured to transfer a signal from the data line 201 to the lower-substrate pixel electrode 203 according to the scanning signal. The second switch unit 204 is a TFT, which has a gate connected to the second gate line 224, a source connected to the data line 201 and a drain connected to the lower-substrate pixel electrode 203. The second switch unit 204 receives a scanning signal from the second gate line 224 and, according to the scanning signal, transfers an electric signal from the data line 201 to the lower-substrate pixel electrode 203 for display driving purpose.

The storage line 205 is disposed in a bottom layer of the pixel structure, and together with the lower-substrate pixel electrode 3, forms a storage capacitor 207.

The first switch unit 206 is configured to transfer the signal from the storage line 205 to the lower-substrate pixel electrode 203 according to the scanning signal.

The first switch unit 206 is a TFT, which has a gate connected to the first gate line 223, a source connected to the storage line 205 and a drain connected to a lower-substrate pixel electrode 203. The first switch unit 206 receives the scanning signal from the first gate line 223 and, according to the scanning signal, transfers an electric signal from the storage line 205 to the lower-substrate pixel electrode 203 to drive the liquid crystal molecules into the operation status in preparation for the UV process.

In this embodiment, the pixel structure can share a first gate line 223 with a pixel structure in an adjacent row, and the two pixel structures are opposite to and inverted from each other. The first gate line 223 is located at a boundary between two adjacent rows of pixel structures so that the first gate line 223 can control two first switch units 206 of the adjacent rows of pixel structures simultaneously to simplify the design.

When the first gate line 223 is enabled, the signal on the storage line 205 is transferred to the lower-substrate pixel electrode 203 of the first switch unit 206 and, consequently, a voltage difference is applied to the liquid crystal molecules between the upper substrate and the lower substrate. Then, a UV process is carried out to fix the pre-tilt angle of the liquid crystal molecules in this operation status.

In this embodiment, instead of using the data line 201, a first gate line 223 is disposed specially for transferring the signal from the storage line 205 to the lower-substrate pixel electrode 203 via the first switch unit 206, so even disconnection of the data line 201 will not affect the curing effect of the UV process.

During use or testing of the LCD panel, the drive circuit uses the second gate line 224 to control turn-on/off of the second switch unit, so normal displaying of images on the LCD panel will not be affected.

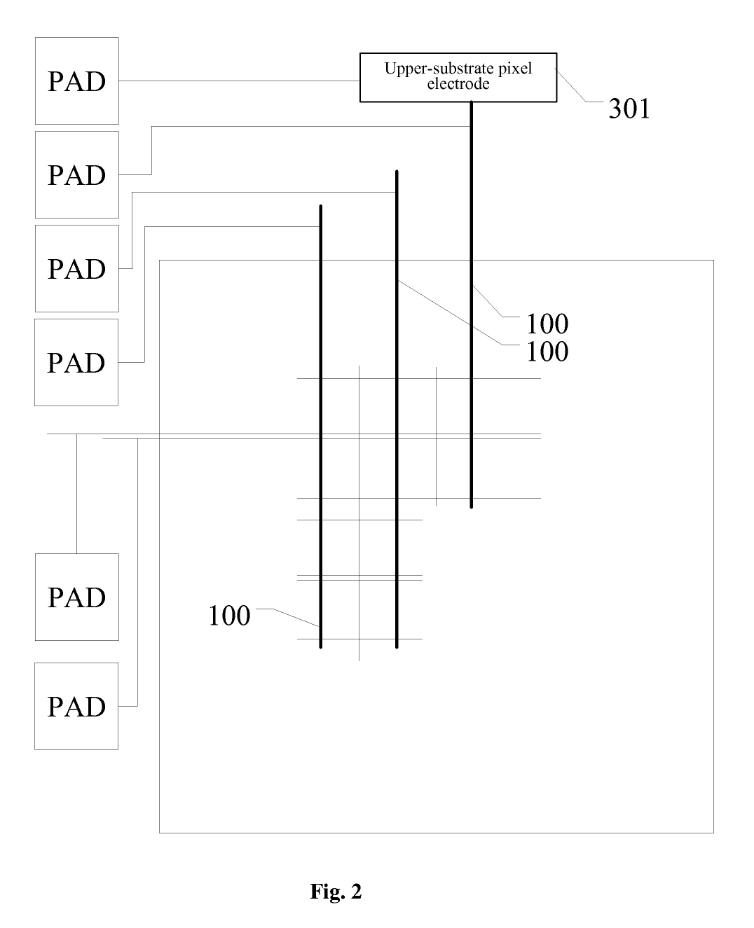

In the prior art, signals are inputted into the pixel via the data line 201, so the data line 201 requires use of three pads (RGB pads) as shown in FIG. 2. However, in this embodiment of the present invention, signals are inputted from the storage line 205 to the lower-substrate pixel electrode 3 not via the data line 201 but via the TFT path disposed between the storage line 205 and the lower-substrate pixel electrode 203, so only three pads are needed (i.e., the number of pads is reduced by four as compared to the prior art) and design of the peripheral circuit becomes further simpler.

The first switch unit 206 and the second switch unit 204 may also be replaced by other switching elements.

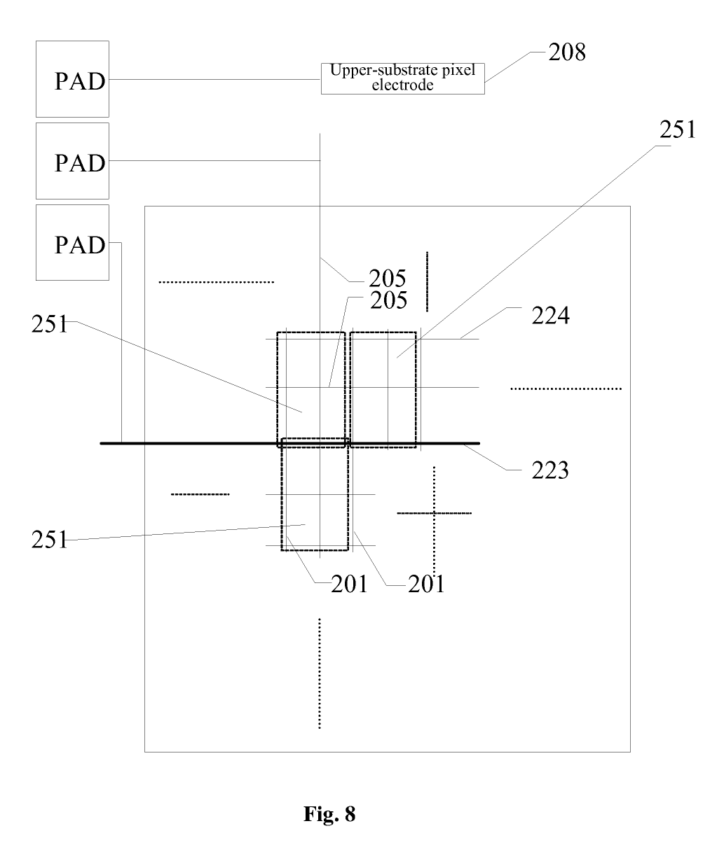

FIG. 8 shows an LCD panel according to the second embodiment of the present invention. A plurality of pixel structures 251 described in the second embodiment are arrayed on an array substrate of the LCD panel, with the data line 201 of each row of pixel structures 251 being connected to an external data driver. For each column of pixel structures 251 on the array substrate, the first gate lines 223 thereof are connected in parallel and the second gate lines 224 are also connected in parallel, and both of them are connected to an external scanning driver. Along a periphery of the array substrate is disposed three pads corresponding to the first gate lines 223, the storage lines 205 and the upper-substrate pixel electrodes 8 respectively. The first gate lines 223 are connected in parallel and then connected together to the corresponding pad; the second gate lines 224 are connected in parallel; the storage lines 205 are connected in parallel and then connected to the corresponding pad; and the upper-substrate pixel electrodes 208 are connected in parallel and then connected together to the corresponding pad.

The structures and working principles of the pixel structures 251 are just the same as those of the embodiment described with reference to FIG. 6 and FIG. 7, and will not be described again herein. In this embodiment, because only when the first gate line 223 is enabled can signals on the storage line 205 be transferred via the TFT path to the lower-substrate pixel electrode 203, and the drive circuit uses the second gate line 224 to input the scanning signal during use or testing of the panel, normal displaying of images on the LCD panel will not be affected.

In this embodiment, the pixel structure can share a first gate line 223 with a pixel structure in an adjacent row, and the two pixel structures are opposite to and inverted from each other. The first gate line 223 is located at a boundary between adjacent rows of pixel structures so that the first gate line 223 can control two first switch units 206 of the adjacent rows of pixel structures simultaneously to simplify the design.

In the prior art, signals are inputted into the pixel via the data line 201, so the data line 201 requires use of three pads (RGB pads). However, in this embodiment of the present invention, signals are inputted from the storage line 205 to the lower-substrate pixel electrode 3 not via the data line 201 but via the TFT path disposed between the storage line 205 and the lower-substrate pixel electrode 203, so the number of pads is reduced by four as compared to the prior art and design of the peripheral circuit becomes further simpler.

What described above are only preferred embodiments of the present invention but are not intended to limit the scope of the present invention. Accordingly, any equivalent structural or process flow modifications that are made on basis of the specification and the attached drawings or any direct or indirect applications in other technical fields shall also fall within the scope of the present invention.

1. A pixel structure for a liquid crystal display (LCD) panel, comprising: a first gate line, a second gate line, a data line, a storage line, a lower-substrate pixel electrode, a first switch unit and a second switch unit, wherein a region enclosed by the first gate line, the second gate line, the data line and an adjacent data line forms a pixel region, and the lower-substrate pixel electrode is located in the pixel region; the first switch unit and the second switch unit are both a thin film transistor (TFT); the first switch unit has a gate connected to the first gate line, a source connected to the storage line and a drain connected to the lower-substrate pixel electrode, and the first switch unit is configured to receive a scanning signal from the first gate line and transfer an electric signal from the storage line to the lower-substrate pixel electrode according to the scanning signal; the second switch unit has a gate connected to the second gate line, a source connected to the data line and a drain connected to the lower-substrate pixel electrode, and the second switch unit is configured to receive a scanning signal from the second gate line and transfer an electric signal from the data line to the lower-substrate pixel electrode according to the scanning signal.

2. The pixel structure of claim 1, further comprising a storage capacitor connected between the storage line and the lower-substrate pixel electrode, wherein an upper-substrate pixel electrode is disposed at a side opposite to the lower-substrate pixel electrode, and liquid crystal molecules are sandwiched between the lower-substrate pixel electrode and the upper-substrate pixel electrode.

3. The pixel structure of claim 2, wherein the data line is connected to an external data driver, and both the first gate line and the second gate line are connected to an external scanning driver.

4. The pixel structure of claim 1, wherein each of the first gate line, the storage line and the upper-substrate pixel electrode is connected with one pad.

5. A pixel structure for an LCD panel, comprising at least one gate line, a storage line, a lower-substrate pixel electrode and a first switch unit,
the at least one gate line is configured to input a scanning signal to the first switch unit;
the first switch unit is connected to the at least one gate line, the storage line and the lower-substrate pixel electrode respectively, and is configured to receive the scanning signal from the at least one gate line and transfer an electric signal from the storage line to the lower-substrate pixel electrode according to the scanning signal.

6. The pixel structure of claim 5, further comprising a data line and a second switch unit, wherein the lower-substrate pixel electrode is located in a pixel region defined by the data line and the gate line, the second switch unit is connected to the at least one gate line, the data line and the lower-substrate pixel electrode respectively, and the second switch unit is configured to receive a scanning signal from the at least one gate line and transfer an electric signal from the data line to the lower-substrate pixel electrode according to the scanning signal.

7. The pixel structure of claim 6, wherein the at least one gate line comprises a charging gate line and a shunting gate line, and the first switch unit comprises a first charging TFT and a first shunting TFT; and
the first charging TFT has a gate connected to the charging gate line, a source connected to the storage line and a drain connected to the first shunting TFT, and the first shunting TFT has a gate connected to the shunting gate line, a source connected to the first charging TFT and a drain connected to the lower-substrate pixel electrode respectively.

8. The pixel structure of claim 7, wherein the data line is connected to an external data driver, and both the charging gate line and the shunting gate line are connected to an external scanning driver.

9. The pixel structure of claim 8, wherein each of the charging gate line, the shunting gate line, the storage line and the upper substrate pixel electrode is connected with one pad.

10. The pixel structure of claim 7, wherein the second switch unit comprises a second charging TFT and a second shunting TFT, the second charging TFT has a gate connected to the charging gate line, a source connected to the data line and a drain connected to the lower-substrate pixel electrode, and the second shunting TFT has a gate connected to the shunting gate line, a source connected to the storage line and a drain connected to the lower-substrate pixel electrode.

11. The pixel structure of claim 5, further comprising a storage capacitor connected between the storage line and the lower-substrate pixel electrode, wherein an upper-substrate pixel electrode is disposed at a side opposite to the lower-substrate pixel electrode, and liquid crystal molecules are sandwiched between the lower-substrate pixel electrode and the upper-substrate pixel electrode.

12. An LCD panel, comprising an array substrate having a plurality of pixel structures arrayed thereon, wherein each of the pixel structures comprises at least one gate line, a storage line, a data line, a lower-substrate pixel electrode, a first switch unit and a second switch unit;
the at least one gate line is configured to input a scanning signal to the first switch unit;
the first switch unit is connected to the at least one gate line, the storage line and the lower-substrate pixel electrode respectively, and is configured to receive the scanning signal from the at least one gate line and transfer an electric signal from the storage line to the lower-substrate pixel electrode according to the scanning signal; and
the lower-substrate pixel electrode is located in a pixel region defined by the data line and the gate line, the second switch unit is connected to the at least one gate line, the data line and the lower-substrate pixel electrode respectively, and the second switch unit is configured to receive a scanning signal from the at least one gate line and transfer an electric signal from the data line to the lower-substrate pixel electrode according to the scanning signal.

13. The LCD panel of claim 12, wherein the at least one gate line comprises a charging gate line and a shunting gate line, and the first switch unit comprises a first charging TFT and a first shunting TFT;
the first charging TFT has a gate connected to the charging gate line, a source connected to the storage line and a drain connected to the first shunting TFT, and the first shunting TFT has a gate connected to the shunting gate line, a source connected to the first charging TFT and a drain connected to the lower-substrate pixel electrode respectively.

14. The LCD panel of claim 13, wherein the second switch unit comprises a second charging TFT and a second shunting TFT, the second charging TFT has a gate connected to the charging gate line, a source connected to the data line and a drain connected to the lower-substrate pixel electrode, and the second shunting TFT has a gate connected to the shunting gate line, a source connected to the storage line and a drain connected to the lower-substrate pixel electrode.

15. The LCD panel of claim 14, wherein each of the charging gate line, the shunting gate line, the storage line and the upper substrate pixel electrode is connected with one pad.

16. The LCD panel of claim 12, wherein the at least one gate line includes a first gate line and a second gate line, and the first switch unit and the second switch unit both are a TFT;
the first switch unit has a gate connected to the first gate line, a source connected to the storage line and a drain connected to a lower-substrate pixel electrode, and the first switch unit is configured to receive a scanning signal from the first gate line and transfer an electric signal from the storage line to the lower-substrate pixel electrode according to the scanning signal; and
the second switch unit has a gate connected to the second gate line, a source connected to the data line and a drain connected to the lower-substrate pixel electrode, and the second switch unit is configured to receive a scanning signal from the second gate line and transfer an electric signal from the data line to the lower-substrate pixel electrode according to the scanning signal.

17. The LCD panel of claim 16, wherein the first gate line is shared by adjacent rows of pixel structures on the array substrate, the first gate line is located at a boundary between the adjacent rows of pixel structures, the data line of each of the pixel structures on the array substrate is connected to an external data driver, and the gate line of each of the pixel structures is connected to an external scanning driver.

18. The LCD panel of claim 16, wherein each of the first gate line, the storage line and the upper-substrate pixel electrode is connected with one pad.
